(19) United States
(12) Patent Application Publication
(10) Pub. No.: US 2025/0207023 A1
(43) Pub. Date: Jun. 26, 2025

(54) Eu-ACTIVATED BETA-SIALON PHOSPHOR PARTICLES, BETA-SIALON PHOSPHOR POWDER, AND LIGHT-EMITTING DEVICE

(71) Applicant: Denka Company Limited, Tokyo (JP)

(72) Inventors: Keita KOBAYASHI, Chuo Tokyo (JP); Tomohiro NOMIYAMA, Chuo Tokyo (JP); Tomonari MIYAZAKI, Chuo Tokyo (JP); Noriyoshi SAKAI, Chuo Tokyo (JP)

(21) Appl. No.: 18/844,036

(22) PCT Filed: Mar. 1, 2023
(86) PCT No.: PCT/JP2023/007644

§ 371 Date: Sep. 4, 2024

(30) Foreign Application Priority Data
Mar. 7, 2022 (JP) 2022-034169

(51) Int. Cl. C09K 11/77; H10H 20/851

(52) U.S. Cl. CPC C09K 11/77348; H10H 20/8512

(57) ABSTRACT

Eu-activated β-sialon phosphor particles having a grain boundary. In a cross-section of the particles including the grain boundary, when line analysis is linearly performed on elemental compositions of the grain boundary and both sides of the grain boundary in a direction perpendicular to the grain boundary at a depth of 200 nm from a portion of surfaces of the particles where the grain boundary is present, on a line segment on which the line analysis is performed, a value of N_{Eu}/N′_{Eu} is less than or equal to 3.00, where (i) N_{Eu} represents an Eu content at a point P of the grain boundary having a peak of the Eu content and (ii) N′_{Eu} represents an Eu content at a point Q at a distance of 50 nm from the point P.

### TECHNICAL FIELD

The present invention relates to Eu-activated β-sialon phosphor particles, β-sialon phosphor powder, and a light-emitting device.

### BACKGROUND ART

There is known a light-emitting device where a light-emitting element that emits primary light is combined with a phosphor that absorbs primary light to emit secondary light.

Recently, as the output of light-emitting devices has increased, the demand for heat resistance and durability of phosphors has increased. Therefore, β-sialon phosphors having a stable crystal structure have attracted attention.

A phosphor containing Eu²⁺ in a β-sialon crystal structure (Eu-activated β-sialon phosphor) that is excited by, for example, blue light to emit green light is known.

The Eu-activated β-sialon is considered as a green light emission component of a light-emitting device such as a white light emitting diode (LED). The Eu-activated β-sialon tends to have a very sharp emission spectrum among phosphors containing Eu. Accordingly, various studies have been conducted on the β-sialon thus far.

For example, Patent Document 1 describes a method for producing a β-sialon phosphor, the method including: a first heat treatment step of heat-treating a mixture containing an aluminum compound, a first europium compound, and silicon nitride to obtain a first heat-treated product; and a second heat treatment step of heat-treating the first heat-treated product with a second europium compound in a rare gas atmosphere to obtain a second heat-treated product.

As another example, Patent Document 2 describes a method for producing a β-sialon phosphor, the method including: a calcination step of calcinating a raw material mixture of the β-sialon phosphor in a nitrogen atmosphere at a temperature of 1820° C. to 2200° C. to obtain a calcinated product; and an annealing step of annealing the calcinated product in a reducing atmosphere at a temperature of higher than or equal to 1100° C.

### RELATED DOCUMENT

### Patent Document

[Patent Document 1] Japanese Unexamined Patent Publication No. 2017-002278
[Patent Document 2] Pamphlet of International Publication No. WO2010/143590

### SUMMARY OF THE INVENTION

### Technical Problem

One object of the present invention is to provide an Eu-activated β-sialon phosphor having an excellent internal quantum efficiency.

### Solution to Problem

The present inventors completed the present invention provided below and achieved the above-described object.

The present invention is as follows.

1. Eu-activated β-sialon phosphor particles having a grain boundary,
in which in a cross-section including the grain boundary, when line analysis is linearly performed on elemental compositions of the grain boundary and both sides of the grain boundary in a direction perpendicular to the grain boundary at a depth of 200 nm from a portion of surfaces of the particles where the grain boundary is present,
on a line segment on which the line analysis is performed, a value of N_{Eu}/N′_{Eu} is less than or equal to 3.00, where (i) N_{Eu} represents an Eu content at a point P of the grain boundary having a peak of the Eu content and (ii) N′_{Eu} represents an Eu content at a point Q at a distance of 50 nm from the point P.

2. The β-sialon phosphor particles according to 1.,
in which a value of (N_{Eu}/N_{O})/(N_{Eu}′/N_{O}′) is less than or equal to 2.00, where N_{O} represents an oxygen content at the point P and N′_{O} represents an oxygen content at the point Q.

3. The β-sialon phosphor particles according to 1, or 2.,
in which a value of N_{Eu}/N_{O} is less than or equal to 0.70, where N_{O} represents an oxygen content at the point P.

4. The β-sialon phosphor particles according to any one of 1. to 3.,
wherein when the line analysis is linearly performed on the elemental compositions of the grain boundary and both sides of the grain boundary in the direction perpendicular to the grain boundary at a depth of 200 nm from the portion of the surfaces of the particles where the grain boundary is present,
on the line segment on which the line analysis is performed, a value of N_{Al}/N_{O} is less than or equal to 1.00, where N_{O} represents an oxygen content at the point P and N_{Al} represents an Al content at a point P_{(Al)} of the grain boundary having a peak of the Al content.

5. Eu-activated β-sialon phosphor particles having a grain boundary,
in which in a cross-section including the grain boundary, when line analysis is linearly performed on elemental compositions of the grain boundary and both sides of the grain boundary in a direction perpendicular to the grain boundary at a depth of 200 nm from a portion of surfaces of the particles where the grain boundary is present,
on a line segment on which the line analysis is performed, a value of N_{Eu(O)}/N′_{Eu(O)} is less than or equal to 2.50, where (i) N_{Eu(O)} represents an Eu content at a point P_{(O)} of the grain boundary having a peak of an O content and (ii) N′_{Eu(O)} represents an Eu content at a point Q_{(O)} at a distance of 50 nm from the point P_{(O)}.

6. The β-sialon phosphor particles according to 5.,
in which a value of (N_{Eu(O)}/N_{O(O)})/(N′_{Eu(O)}/N′_{O(O)}) is less than or equal to 1.20, where N_{O(O)} represents an oxygen content at the point P_{(O)} and N′_{O(O)} represents an oxygen content at the point Q_{(O)}.

7. The β-sialon phosphor particles according to 5, or 6.,
in which a value of N_{Eu(O)}/N_{O(O)} is less than or equal to 0.70, where N_{O(O)} represents an oxygen content at the point P_{(O)}.

8. The β-sialon phosphor particles according to any one of 5. to 7.,
in which a value of N_{Al(O)}/N_{O(O)} is less than or equal to 1.00, where N_{O(O)} represents an oxygen content at the point P_{(O)} and N_{Al(O)} represents an aluminum content at the point P_{(O)}.

9. β-sialon phosphor powder including the β-sialon phosphor particles according to any one of 1. to 8.

10. A light-emitting device including:
a light-emitting light source; and
a wavelength conversion member,
in which the wavelength conversion member contains phosphor powder, and
the phosphor powder contains the β-sialon phosphor powder according to 9.

11. The light-emitting device according to 10.,
in which the light-emitting light source includes an LED chip that generates light having a wavelength of more than or equal to 300 nm and less than or equal to 500 nm.

### Advantageous Effects of Invention

According to the present invention, an Eu-activated β-sialon phosphor having an excellent internal quantum efficiency is provided.

### BRIEF DESCRIPTION OF THE DRAWINGS

FIG. 1 A cross-sectional view schematically showing an example of a structure of a light-emitting device.

FIG. 2 A diagram showing measurement positions of line analysis according to Example 1.

FIG. 3 A diagram showing measurement positions of line analysis according to Comparative Example 1.

### DESCRIPTION OF EMBODIMENTS

Hereinafter, embodiments of the present invention will be described in detail with reference to the drawings.

In the present specification, Eu-activated β-sialon phosphor particles will be simply referred to as β-sialon phosphor particles.

In the present specification, “grain boundary” refers to a discontinuous boundary surface between one crystal and another crystal. In the grain boundary, two or more crystals (crystal grains) are in contact with each other in a state where orientations thereof are different.

In the present specification, “surfaces of the particles” of the β-sialon phosphor particles refer to at least any one of the following cases:
(i) a boundary between the β-sialon phosphor particle in the atmosphere and the atmosphere;
(ii) a boundary between a layer containing at least one of amorphous Si, Al, O, N, Eu, and the like present on the surface of the β-sialon phosphor particle in the atmosphere and the atmosphere; and
(iii) a boundary between a layer containing at least one of Si, Al, O, N, Eu, and the like present as a crystal phase on the surface of the β-sialon phosphor particle in the atmosphere and the atmosphere.

“The surface of the particle” can also be referred to as a boundary between a position where at least one of Si, Al, O, N, Eu, and the like is detected and a position where at least one of Si, Al, O, N, Eu, and the like is not detected in elemental distribution analysis by energy dispersive X-ray spectroscopy (EDS).

In the present specification, the expression “X to Y” in the description of a numerical range represents more than or equal to X and less than or equal to Y unless specified otherwise. For example, “1 to 5 mass %” represents “more than or equal to 1 mass % and less than or equal to 5 mass %”.

### First Embodiment: β-Sialon Phosphor Particles

β-sialon phosphor particles according to a first embodiment have a grain boundary.

In a cross-section including the grain boundary, line analysis is linearly performed on elemental compositions of the grain boundary and both sides of the grain boundary in a direction perpendicular to the grain boundary at a depth of 200 nm from a portion of surfaces of the particles where the grain boundary is present.

At this time, on a line segment on which the line analysis is performed, a value of N_{Eu}/N′_{Eu} is less than or equal to 3.00, where (i) N_{Eu} represents an Eu content at a point P of the grain boundary having a peak of the Eu content and (ii) N′_{Eu} represents an Eu content at a point Q at a distance of 50 nm from the point P.

The value of N_{Eu}/N′_{Eu} being less than or equal to 3.00 represents that, at a relatively small depth of 200 nm in the particle, the Eu content at the point P corresponding to the grain boundary is less than or equal to 3 times the Eu content at the point Q at a sufficient distance (50 nm) from the point P.

In consideration of findings of the present inventors or past study results, it is considered that elemental Eu that is not completely dissolved in crystals of a β-sialon phosphor in the related art is unevenly distributed in the grain boundary. That is, it is considered that the value of the N_{Eu}/N′_{Eu} of the β-sialon phosphor in the related art is large at more than 3.00 (note: Comparative Example described below).

Typically, Eu functions as the emission center by being dissolved in the crystals. However, when Eu is unevenly distributed in the grain boundary, unintended light absorption (light absorption not contributing to fluorescence) occurs in the grain boundary and the vicinity thereof, and thus an internal quantum efficiency may deteriorate.

In the β-sialon phosphor particles according to the first embodiment, at a relatively small depth of 200 nm in the particle, the Eu content in the portion corresponding to the grain boundary is relatively low. Therefore, it is considered that unintended light absorption is not likely to occur in the grain boundary and the vicinity thereof. As a result, it is considered that the internal quantum efficiency of the β-sialon phosphor particles according to the first embodiment is excellent.

Incidentally, the point Q may be present “at two points on both sides” of the point P. When at least one of the two points is the point Q, the value of N_{Eu}/N′_{Eu} may be less than or equal to 3.00. In consideration of the above-described estimation mechanism, it is presumed that the effect of improving the internal quantum efficiency can be obtained as long as the value of N_{Eu}/N′_{Eu} at least one among the two points Q that may be present “at the two points on both sides” of the point P is less than or equal to 3.00.

The β-sialon phosphor particles according to the first embodiment can be produced by using an appropriate material and adopting appropriate a production method and production conditions. Preferably, by adding a small amount of titanium oxide (Ti₂O₃) to the β-sialon phosphor for annealing, the Eu content in the grain boundary can be reduced. The production method will be described in detail below.

The value of N_{Eu}/N′_{Eu} may be less than or equal to 3.00 and is preferably more than or equal to 0.01 and less than or equal to 3.00, more preferably more than or equal to 0.10 and less than or equal to 3.00, still more preferably more than or equal to 0.50 and less than or equal to 3.00, and still more preferably more than or equal to 1.00 and less than or equal to 3.00.

Here, a procedure of performing line analysis, that is, continuously performing elemental analysis on a line segment having a fixed length on a cross-section of the phosphor particle including the grain boundary will be described. The more details of the procedure can be found in Examples described below.
(1) A sample where the β-sialon phosphor particles are embedded with a resin material such as an epoxy resin is prepared.
(2) The sample prepared in (1) above is set in a cross-section polisher. A cross-section of the embedded β-sialon phosphor particles is exposed.
(3) The cross-section exposed in (2) above is observed with an electron microscope to specify a portion where a grain boundary (substantially linear grain boundary having a length of at least 200 nm from the particle surface) suitable for analysis is present. This portion and the periphery thereof are thinned by a focused ion beam (FIB) processing device to prepare a thin sample.
(4) In the thin sample (cross-section including the grain boundary), line analysis is linearly performed on elemental compositions of the grain boundary and both sides of the grain boundary in a direction perpendicular to the grain boundary at a depth of 200 nm from a portion of surfaces of the particles where the grain boundary is present. In the line analysis, an apparatus where a scanning transmission electron microscope (STEM) and an instrument capable of energy dispersive X-ray spectroscopy (EDS) are combined can be used.
(5) The content (unit: atom %) of each of elements at each of the points such as the point P is obtained based on the result of the line analysis. A “ratio” between the element contents, for example, N_{Eu}/N′_{Eu} is calculated from the obtained content of each of the elements.

The description regarding the β-sialon phosphor particles according to the first embodiment will be continued.

### Composition of β-Sialon Phosphor

The β-sialon phosphor is typically a phosphor formed of β-sialon in which Eu²⁺ is dissolved, represented by Formula Si_{6-z}Al_{z}O_{z}N_{8-z}:Eu²⁺ₐ (0<Z≤4.2, 0.001<a<1.0).

In Formula Si_{6-z}Al_{z}O_{z}N_{8-z}:Eu²⁺ₐ, the Z value and the europium content are not particularly limited. The Z value is, for example, more than 0 and less than or equal to 4.2. In addition, from the viewpoint of further improving the emission intensity of the β-sialon phosphor, a is more than or equal to 0.001 and less than or equal to 1.0. In addition, the europium content is preferably more than or equal to 0.1 mass % and less than or equal to 2.0 mass %.

Value of (N_{Eu}/N_{O})/(N_{Eu}′/N_{O}′)

The Eu content in the β-sialon phosphor is typically less than those of other major elements (Si, Al, O, and N). Accordingly, by comparing the Eu content to the oxygen (O) content, it can be more clearly expressed that the Eu content in the grain boundary is relatively low.

Specifically, a value of (N_{Eu}/N_{O})/(N′_{Eu}/N′_{O}) where N_{O} represents an oxygen content at the point P and N′_{O} represents an oxygen content at the point Q is preferably less than or equal to 2.00, more preferably more than or equal to 0.01 and less than or equal to 2.00, still more preferably more than or equal to 0.020 and less than or equal to 2.00, and still more preferably more than or equal to 0.03 and less than or equal to 1.80.

Value of N_{Eu}/N_{O}

The value of N_{Eu}/N′_{Eu} is less than or equal to 3.00, that is, the “ratio” between the Eu contents at the point P and the point Q is not too high, and the Eu content in the grain boundary is not too higher than those of other elements. As a result, it is considered that unintended light absorption in the grain boundary and the vicinity thereof is suppressed, which leads to further improvement in internal quantum efficiency.

Specifically, the value of N_{Eu}/N_{O}, that is, the ratio Eu content/O content in the grain boundary (depth: 200 nm) is preferably less than or equal to 0.70, more preferably more than or equal to 0.001 and less than or equal to 0.70, still more preferably more than or equal to 0.005 and less than or equal to 0.50, and still more preferably more than or equal to 0.005 and less than or equal to 0.40.

Value of N_{Al}/N_{O}

Even when the Al content in the grain boundary is not too higher than those of other elements, further improvement in internal quantum efficiency can be expected.

Although the details are not clear, based on the past finding, a charge defect called an aluminum oxygen hole center may be present in the vicinity of the grain boundary that is presumed to be in a glass state. It is considered that, when the Al content in the vicinity of the grain boundary is low, the number of charge defects is reduced, and the internal quantum efficiency is further improved.

Specifically, when the line analysis is linearly performed on the elemental compositions of the grain boundary and both sides of the grain boundary in the direction perpendicular to the grain boundary at a depth of 200 nm from the portion of the surfaces of the particles where the grain boundary is present,
on the line segment on which the line analysis is performed, a value of N_{Al}/N_{O} where N_{Al} represents an Al content at a point P_{(Al)} of the grain boundary having a peak of the Al content, that is, a ratio Al content/O content in the vicinity of the grain boundary at a depth of 200 nm is preferably less than or equal to 1.0, more preferably more than or equal to 0.01 and less than or equal to 1.00, still more preferably more than or equal to 0.01 and less than or equal to 0.70, and still more preferably more than or equal to 0.05 and less than or equal to 0.50.

In addition, a value of (N_{Al}/N_{O})/(N′_{Al}/N′_{O}) where N′_{Al} represents an aluminum content at the point Q is preferably less than or equal to 0.47 and more preferably more than or equal to 0.01 and less than or equal to 0.47 (the definition of N′_{O} is as described above). In addition, the value of N_{Al}/N′_{Al} is preferably less than or equal to 1.10, more preferably more than or equal to 0.10 and less than or equal to 1.10, still more preferably more than or equal to 0.50 and less than or equal to 1.10, and still more preferably more than or equal to 0.75 and less than or equal to 1.10.

### Supplement on Content of Each of Elements

Just to be sure, numerical ranges of N_{Eu} and the like will be described below.

The value of N_{Eu} is typically more than or equal to 0.00 atom % and less than or equal to 1.50 atom %, preferably more than or equal to 0.05 atom % and less than or equal to 1.00 atom %, more preferably more than or equal to 0.10 atom % and less than or equal to 0.50 atom %, still more preferably more than or equal to 0.10 atom % and less than or equal to 0.30 atom %.

The value of N′_{Eu} is typically more than or equal to 0.01 atom % and less than or equal to 1.00 atom %, preferably more than or equal to 0.01 atom % and less than or equal to 0.80 atom %, more preferably more than or equal to 0.02 atom % and less than or equal to 0.50 atom %, still more preferably more than or equal to 0.03 atom % and less than or equal to 0.25 atom %.

The value of N_{O} is typically more than or equal to 0.10 atom % and less than or equal to 20.00 atom %, preferably more than or equal to 0.30 atom % and less than or equal to 20.00 atom %, more preferably more than or equal to 0.50 atom % and less than or equal to 15.00 atom %.

The value of N′_{O} is typically more than or equal to 0.01 atom % and less than or equal to 10.00 atom %, preferably more than or equal to 0.05 atom % and less than or equal to 10.00 atom %, and more preferably more than or equal to 0.10 atom % and less than or equal to 10.00 atom %.

The value of N_{Al} is typically more than or equal to 0.00 atom % and less than or equal to 10.00 atom % and preferably more than or equal to 0.00 atom % and less than or equal to 3.50 atom %.

The value of N′_{Al} is typically more than or equal to 0.50 atom % and less than or equal to 10.00 atom %, preferably more than or equal to 0.50 atom % and less than or equal to 5.00 atom %, and more preferably more than or equal to 1.00 atom and less than or equal to 5.00 atom %.

An N content N_{N} at the point P is typically more than or equal to 5.00 atom % and less than or equal to 40.00 atom %, preferably more than or equal to 10.00 atom % and less than or equal to 35.00 atom %, and more preferably more than or equal to 10.00 atom % and less than or equal to 30.00 atom %.

An N content N′_{N} at the point Q is typically more than or equal to 5.00 atom % and less than or equal to 40.00 atom, preferably more than or equal to 10.00 atom % and less than or equal to 35.00 atom %, more preferably more than or equal to 10.00 atom % and less than or equal to 30.00 atom %, still more preferably more than or equal to 10.00 atom % and less than or equal to 25.00 atom %.

A Si content N_{Si} at the point P is typically more than or equal to 50.00 atom % and less than or equal to 85.00 atom % and preferably more than or equal to 60.00 atom % and less than or equal to 80.00 atom %.

A Si content N′_{Si} at the point Q is typically more than or equal to 50.00 atom % and less than or equal to 85.00 atom %, preferably more than or equal to 60.00 atom % and less than or equal to 80.00 atom %, more preferably more than or equal to 70.00 atom % and less than or equal to 80.00 atom %, still more preferably more than or equal to 75.00 atom % and less than or equal to 80.00 atom %.

Incidentally, as described below, Ti is preferably used in a step of producing the β-sialon phosphor particles according to the first embodiment. It is ideal that Ti is used only for the production step and does not remain in the final β-sialon phosphor particles. Actually, however, a small amount of Ti may remain.

A Ti content N_{Ti} at the point P is preferably less than or equal to 0.50 atom % and more preferably less than or equal to 0.20 atom %. N_{Ti} is ideally zero (the content less than or equal to the detection limit).

A Ti content N′_{Ti} at the point Q is preferably less than or equal to 0.50 atom %, more preferably less than or equal to 0.20 atom %, and still more preferably less than or equal to 0.10 atom %. N′_{Ti} is ideally zero (the content less than or equal to the detection limit).

### β-Sialon Phosphor Powder

β-sialon phosphor powder according to the first embodiment contains the β-sialon phosphor particles according to the first embodiment.

A 50% cumulative diameter (D50) in a volume-based cumulative particle size distribution of the β-sialon phosphor powder can be adjusted depending on the use or the like of the phosphor.

D50 is, for example, more than or equal to 0.1 μm and less than or equal to 50 μm, preferably more than or equal to 3 μm and less than or equal to 40 μm, and more preferably more than or equal to 6 μm and less than or equal to 30 μm. D50 can be controlled by adjusting conditions such as a heating temperature and a heating time during production of the phosphor or by performing appropriate grinding, classification, and the like.

D50 is defined as a particle size at which a cumulative value from the smallest particle size reaches 50% of the total value in a volume-based particle size distribution curve measured using a laser diffraction scattering method. The distribution curve regarding the particle sizes of the phosphor can be obtained with a particle size distribution measuring method using a laser diffraction scattering method described in JIS R 1629:1997 “Determination Of Particle Size Distributions for Fine Ceramic Raw Powders by Laser Diffraction Scattering Method”. For the measurement, a particle size distribution analyzer can be used.

Specifically, first, 0.1 g of the phosphor to be measured is put into 100 mL of ion exchange water, a small amount of sodium hexametaphosphate is added, and the solution is dispersed using an ultrasonic homogenizer for 3 minutes to obtain a dispersion liquid. Using this dispersion liquid as a measurement sample, a particle size distribution is measured using a particle size distribution analyzer. D50 is determined from the obtained particle size distribution.

As the particle size distribution analyzer, for example, “Microtrac MT3300EX II” (product name) manufactured by MicrotracBEL Corp. can be used. As the ultrasonic homogenizer, for example, “Ultrasonic Homogenizer US-150E” (product name, chip size: φ20, amplitude: 100%, oscillation frequency: 19.5 KHz, amplitude: about 31 μm) manufactured by NISSEI Corporation can be used.

### Second Embodiment: β-Sialon Phosphor Particles

β-sialon phosphor particles according to a second embodiment have a grain boundary.

In a cross-section including the grain boundary, when line analysis is linearly performed on elemental compositions of the grain boundary and both sides of the grain boundary in a direction perpendicular to the grain boundary at a depth of 200 nm from a portion of surfaces of the particles where the grain boundary is present, on a line segment on which the line analysis is performed, a value of N_{Eu(O)}/N′_{Eu(O)} is less than or equal to 2.50, where (i) N_{Eu(O)} represents an Eu content at a point P_{(O)} of the grain boundary having a peak of an O content and (ii) N′_{Eu(O)} represents an Eu content at a point Q_{(O)} at a distance of 50 nm from the point P_{(O)}.

In the first embodiment, the β-sialon phosphor particles where the ratio between (i) the Eu content (N_{Eu}) at “the point P of the grain boundary having a peak of the Eu content” and (ii) the Eu content (N′_{Eu}) at the point Q at a distance of 50 nm from the point P is in the certain range are specified. In other words, in the first embodiment, “the point P having a peak of the Eu content” is set as “reference position” in the grain boundary that is observed with a limited width.

On the other hand, in the second embodiment, β-sialon phosphor particles where a ratio between (i) an Eu content (N_{Eu(O)}) at “a point P_{(O)} of the grain boundary having a peak of an O content” and (ii) an Eu content (N′_{Eu(O)}) at a point Q_{(O)} at a distance of 50 nm from the point P_{(O)} is in a certain range are specified. In other words, in the second embodiment, “the point P_{(O)} having a peak of the O content” is set as “reference position” in the grain boundary that is observed with a limited width.

That is, although the positions for measuring the element contents such as the Eu content are slightly different, the first embodiment and the second embodiment are similar to each other.

Incidentally, the reason why different “reference positions” are provided in the first embodiment and the second embodiment is based on the finding of the present inventors. Specifically, as a result of the measurement by the present inventors, the reason is that the point having a peak of the Eu content and the point having a peak of the O content in the grain boundary do not necessarily match with each other and each of the points can be considered as “the center of the grain boundary” in the grain boundary observed with a limited width.

As in the description of the first embodiment, it can be said that the value of N_{Eu(O)}/N′_{Eu(O)} being less than or equal to 2.5 represents that, at a relatively small depth of 200 nm in the particle, the Eu content in the portion corresponding to the grain boundary is relatively low. That is, it is considered that, even in the β-sialon phosphor particles according to the second embodiment, unintended light absorption is not likely to occur in the grain boundary and the vicinity thereof, and thus the internal quantum efficiency is excellent.

The value of N_{Eu(O)}/N′_{Eu(O)} may be less than or equal to 2.50 and is preferably more than or equal to 0 and less than or equal to 3.00, more preferably more than or equal to 0 and less than or equal to 2.00, and still more preferably more than or equal to 0 and less than or equal to 1.50.

Hereinafter, the description regarding the β-sialon phosphor particles according to the second embodiment will be continued. Incidentally, as described above, since the first embodiment and the second embodiment are similar to each other, the features described in the first embodiment are appropriately applicable to the second embodiment.

As in the first embodiment, the chemical composition of the β-sialon phosphor particles according to the second embodiment can be represented by Formula Si_{6-z}Al_{z}O_{z}N_{8-z}:Eu²⁺ₐ (0<Z≤4.2, 0.001<a<1.0).

Even in the second embodiment, by comparing the Eu content to the oxygen (O) content, it can be more clearly expressed that the Eu content in the grain boundary is relatively low.

Specifically, a value of (N_{Eu(O)}/N_{O(O)})/(N′_{Eu(O)}/N′_{O(O)}) where N_{O(O)} represents an oxygen content at the point P_{(O)} and N′_{O(O)} represents an oxygen content at the point Q_{(O)} is preferably less than or equal to 1.20, more preferably more than or equal to 0 and less than or equal to 1.20, still more preferably more than or equal to 0 and less than or equal to 1.00, still more preferably more than or equal to 0 and less than or equal to 0.50, and still more preferably more than or equal to 0 and less than or equal to 0.30.

Even in the second embodiment, the Eu content in the grain boundary is not too higher than those of other elements. As a result, it is considered that unintended light absorption in the grain boundary and the vicinity thereof is suppressed, which leads to further improvement in internal quantum efficiency.

Specifically, a value of N_{Eu(O)}/N_{O(O)} where N_{O(O)} represents an oxygen content at the point P_{(O)} is preferably less than or equal to 0.70, more preferably more than or equal to 0 and less than or equal to 0.70, still more preferably more than or equal to 0 and less than or equal to 0.50, still more preferably more than or equal to 0 and less than or equal to 0.30, and still more preferably more than or equal to 0 and less than or equal to 0.10.

Even in the second embodiment, when the Al content in the grain boundary is not too higher than those of other elements, further improvement in internal quantum efficiency can be expected.

Specifically, a value of N_{Al(O)}/N_{O(O)} where N_{O(O)} represents an oxygen content at the point P_{(O)} and N_{Al(O)} represents an aluminum content at the point P_{(O)} is preferably less than or equal to 1.00, more preferably more than or equal to 0 and less than or equal to 1.00, and still more preferably more than or equal to 0.01 and less than or equal to 1.00.

In addition, a value of (N_{Al(O)}/N_{O(O)}/(N′_{Al(O)}/N′_{O(O)}) where N′_{Al(O)} represents an aluminum content at the point Q_{(O)} is preferably less than or equal to 0.45, more preferably more than or equal to 0 and less than or equal to 0.45, still more preferably more than or equal to 0 and less than or equal to 0.30, and still more preferably more than or equal to 0.005 and less than or equal to 0.25.

In addition, the value of N_{Al(O)}/N′_{Al(O)} is preferably less than or equal to 1.10, more preferably more than or equal to 0.1 and less than or equal to 1.10, still more preferably more than or equal to 0.50 and less than or equal to 1.10, and still more preferably more than or equal to 0.75 and less than or equal to 1.10.

The value of N_{Eu(O)} is typically less than or equal to 1.50 atom %, preferably more than or equal to 0 atom % and less than or equal to 1.00 atom %, more preferably more than or equal to 0 atom % and less than or equal to 0.50 atom %, and still more preferably more than or equal to 0 atom % and less than or equal to 0.30 atom %.

The value of N′_{Eu(O)} can be the same as N′_{Eu}.

The value of N_{O(O)} is typically more than or equal to 1.00 atom and less than or equal to 50.0 atom %, preferably more than or equal to 1.00 atom and less than or equal to 45.0 atom %, and more preferably more than or equal to 1.00 atom % and less than or equal to 40.0 atom %.

The value of N′_{O(O)} can be the same as N′_{O}.

The value of N_{Al(O)} is typically more than or equal to 0.10 atom % and less than or equal to 10.00 atom %, preferably more than or equal to 0.10 atom % and less than or equal to 5.00 atom %, and more preferably more than or equal to 0.10 atom % and less than or equal to 3.00 atom %.

The value of N′_{Al(O)} can be the same as N′_{Al}.

An N content N_{N(O)} at the point P_{(O)} is typically more than or equal to 5.00 atom % and less than or equal to 40.00 atom %, preferably more than or equal to 5.00 atom % and less than or equal to 30.00 atom %, and more preferably more than or equal to 5.00 atom % and less than or equal to 25.00 atom %.

β-sialon phosphor powder according to the second embodiment contains the β-sialon phosphor particles according to the second embodiment.

A 50% cumulative diameter (D50) in a volume-based cumulative particle size distribution of the β-sialon phosphor powder according to the second embodiment can be the same as that of the β-sialon phosphor powder according to the first embodiment.

### <Method for Producing B-Sialon Phosphor Particles>

The β-sialon phosphor particles according to the first embodiment and the β-sialon phosphor particles according to the second embodiment can be produced by using an appropriate material and adopting appropriate a production method and production conditions.

Preferable examples of the production method include a method of adding a small amount of titanium oxide (Ti₂O₃) to the β-sialon phosphor for annealing. As a result, the Eu content in the grain boundary can be reduced.

Although the details of the mechanism are not clear, based on the past finding of the present inventors, it is considered that, through the above-described annealing treatment, a compound containing Eu and Ti is formed in the grain boundary of the phosphor particles and the vicinity thereof. It is considered that, since the compound is removed through an acid treatment described below, the Eu content in the grain boundary and the vicinity thereof is controlled.

In addition, it is considered that, since not only (i) the compound containing Eu and Ti but also (ii) the compound containing Al and Ti are formed, the Al content in the grain boundary and the vicinity thereof is also controlled.

One example of the production method can be a method including:
a calcination step of obtaining a calcinated product containing β-sialon from a raw material composition containing a silicon source, an aluminum source, and a europium source at least one of which is a nitride by performing a heat treatment once or more times; and
an annealing step of obtaining an annealed product from a mixture containing the calcinated product and titanium oxide (Ti₂O₃) by performing an annealing treatment once or more times in an atmosphere containing at least one selected from the group consisting of rare gas, reducing gas, and inert gas. Hereinafter, this example will be described.

The raw material composition contains a compound having elements as constituent elements of β-sialon containing europium, and can contain at least a silicon source, an aluminum source, and a europium source.

In the raw material composition, at least one of the silicon source, the aluminum source, and the europium source is a nitride. The nitride contains nitrogen as a constituent element of β-sialon, and thus also functions as a nitrogen source. The silicon source refers to a compound or a simple substance containing silicon as a constituent element, the aluminum source refers to a compound or a simple substance containing aluminum as a constituent element, and the europium source refers to a compound or a simple substance containing europium as a constituent element. In the present specification, the compound containing silicon as a constituent element will also be referred to as the silicon compound, the compound containing aluminum as a constituent element will also be referred to as the aluminum compound, and the compound containing europium as a constituent element will also be referred to as the europium compound. Each of the silicon compound, the aluminum compound, and the europium compound may be any one of a nitride, an oxide, an oxynitride, and a hydroxide. In addition, the raw material composition may further contain β-sialon or europium-containing β-sialon. Here, the β-sialon or the europium-containing β-sialon is a material as an aggregate or a core.

Examples of the silicon compound include silicon nitride (Si₃N₄) and silicon oxide (SiO₂). As the silicon nitride, silicon nitride having a high a fraction is preferably used. The a fraction of the silicon nitride may be, for example, more than or equal to 80 mass %, more than or equal to 90 masse, or more than or equal to 95 mass %. When the a fraction of the silicon nitride is in the above-described range, primary particle growth can be promoted. As the silicon nitride, silicon nitride having a low oxygen content is preferably used. The oxygen content in the silicon nitride may be, for example, less than or equal to 3.0 mass % or less than or equal to 1.3 mass %. When the oxygen content in the silicon nitride is in the above-described range, the occurrence of defects in the crystals of the β-sialon can be suppressed.

Examples of the aluminum compound include aluminum nitride (AlN), aluminum oxide (Al₂O₃), and aluminum hydroxide (Al(OH)₃).

Examples of the europium compound include an oxide of europium (europium oxide), a nitride of europium (europium nitride), and a halide of europium. Examples of the halide of europium include europium fluoride, europium chloride, europium bromide, and europium iodide. It is preferable that the europium compound contains europium oxide. The valence of europium in the europium compound may be divalent or trivalent and is preferably divalent.

The raw material mixture can be prepared by weighing each of the compounds and mixing the compounds. For the mixing, a dry mixing method or a wet mixing method can be used. The dry mixing method may be, for example, a method of mixing the components using a V-shape mixer. The wet mixing method can be, for example, a method of adding a solvent such as water or a dispersion medium to prepare a solution or a slurry, mixing the components, and subsequently removing the solvent or the dispersion medium.

The heating temperature in the calcination step is, for example, 1800° C. to 2500° C., 1800° C. to 2400° C., 1850° C. to 2100° C., 1900° C. to 2100° C., 1900° C. to 2050° C., or 1920° C. to 2050° C.

By setting the heating temperature in the calcination step to be higher than or equal to 1800° C., the particle growth of the β-sialon can be promoted, and the solid solution amount of europium can be made more sufficient. By setting the heating temperature in the calcination step to be lower than or equal to 2500° C., the decomposition of the crystals of the β-sialon can be sufficiently suppressed.

From the viewpoint of promoting the primary particle growth of the β-sialon, the heating time in the calcination step may be long. When the heating time is excessively long, the number of crystal defects can increase. Therefore, the heating time is, for example, 1 to 30 hours, 3 to 25 hours, or 5 to 20 hours.

The heating of the raw material mixture in the calcination step is performed, for example, in a nitrogen atmosphere. By performing heating under a condition where a nitrogen partial pressure is high, the decomposition of silicon nitride at a high temperature can be suppressed. In addition, the particle growth can be promoted by performing the treatment at a high temperature. The heating of the raw material mixture in the calcination step is performed, for example, under pressure. The pressure at this time may be, for example, 0.010 to 200 MPaG, 0.020 to 200 MPaG, 0.1 to 200 MPaG, 0.1 to 100 MPaG, 0.1 to 50 MPaG, 0.1 to 15 MPaG, or 0.1 to 5 MPaG.

The number of times of the heat treatment in the calcination step may be one, two or more, two to five, or two to four. By performing the heat treatment multiple times, β-sialon phosphor having a higher emission intensity can be obtained.

In the calcination step, the heat treatment is performed once or more times. When the heat treatment is performed multiple times, the heat treatments will also be referred to as a first heat treatment, a second heat treatment, and the like in order, and steps of performing the respective heat treatments will also be referred to as a first calcination step, a second calcination step, and the like in order. For example, in the above-described production method, when the heat treatment is performed twice in the calcination step, it can be said that the calcination step includes: a step of obtaining a first heat-treated product by performing the first heat treatment on the raw material composition containing a nitride; and a second calcination step of obtaining a second heat-treated product by performing the second heat treatment on the first heat-treated product. In this case, the second heat-treated product corresponds to a calcinated product containing β-sialon. Before performing the heat treatment multiple times, the silicon source, the aluminum source, and the europium source may be further mixed to perform the heat treatment.

When the heat treatment is performed two or more times in the calcination step, the heating temperature, the heating time, the atmosphere during heating, and the pressure during heating in the above-described heating step are applicable to the heating temperature, the heating time, the atmosphere during heating, and the pressure during heating in the first calcination step, respectively. The heating temperature, the heating time, the atmosphere during heating, and the pressure during heating in and after the second calcination step may be the same as or different from those of the first calcination step. Note that, even when the heating temperature, the heating time, the atmosphere during heating, and the pressure during heating in and after the second calcination step are different from those of the first calcination step, these conditions are in the ranges of the conditions described regarding the above-described heating step.

The calcinated product obtained in the calcination step contains β-sialon crystals, a part thereof is a solid solution where an element as the emission center is dissolved, and the solid solution itself can emit fluorescence. Since the calcinated product obtained in the calcination step may be in a lump, the particle size may be adjusted by crushing or the like before the annealing step.

Next, the annealing step is performed. The annealing step in the production method in the present example refers to a step of annealing a mixture containing the calcinated product obtained in the above-described calcination step and titanium oxide (Ti₂O₃). In the annealing step, an annealed product is obtained from the mixture by performing the heat treatment once or more times.

The blending amount of the titanium oxide (Ti₂O₃) can be, for example, 0.01 to 4 mass %, 0.05 to 3 mass %, or 0.1 to 3 mass % with respect to the total amount of the mixture.

By adjusting the blending amount to be more than or equal to 0.01 mass %, redundant Eu or Al in the grain boundary can be sufficiently removed, and the internal quantum efficiency of the obtained β-sialon phosphor can be further improved.

By adjusting the blending amount to be less than or equal to 4 mass %, titanium oxide or various products can be easily removed through the acid treatment, and a decrease in emission characteristics of the β-sialon phosphor can be suppressed.

In the annealing step, the annealing treatment is performed in an atmosphere containing at least one selected from the group consisting of rare gas, reducing gas, and inert gas. By performing the annealing treatment in the atmosphere containing rare gas, reducing gas, or inert gas, the proportion of divalent europium in the europium of the solid solution can be increased.

The rare gas may contain, for example, argon or helium, and may contain argon or may consist of argon. The reducing gas may contain, for example, ammonia, hydrocarbon, carbon monoxide, or hydrogen, and may contain hydrogen or may consist of hydrogen. The inert gas may contain, for example, nitrogen, or may consist of nitrogen. The atmosphere of the annealing step may be mixed gas of two or more kinds among the rare gas, the reducing gas, and the inert gas. When the atmosphere in the annealing step is the mixed gas, the content of the reducing gas may be, for example, 1 to 50 vol % or 4 to 20 vol % with respect to the total volume of the mixed gas. The content of the inert gas may be, for example, 1 to 50 vol % or 4 to 20 vol % with respect to the total volume of the mixed gas.

The pressure during the annealing treatment may be the same as the pressure in the calcination step but is preferably lower than the pressure condition in the calcination step and more preferably the atmospheric pressure.

The temperature during the annealing treatment needs to be set to be lower than the heating temperature in the calcination step. The upper limit value of the temperature during the annealing treatment is, for example, lower than or equal to 1700° C. and preferably lower than or equal to 1680° C. By setting the upper limit value of the temperature during the annealing treatment to be in the above-described range, coarsening of the particles caused by the occurrence of aggregation, formation of secondary particles, or the like between the solid solutions due to further progress of particle growth in the calcinated product can be suppressed. The lower limit value of the temperature during the annealing treatment is, for example, higher than or equal to 1000° C., higher than or equal to 1100° C., higher than or equal to 1200° C., higher than or equal to 1300° C., or higher than or equal to 1400° C. By setting the lower limit value of the temperature during the annealing treatment to be in the above-described range, the β-sialon crystal defect density in the annealed product can be reduced, and the internal quantum efficiency can be further improved. The temperature during the annealing treatment can be adjusted to be in the above-described range, for example, 1000° C. to 1700° C. or 1100° C. to 1680° C.

From the viewpoint of further reducing crystal defects in the phosphor of the annealed product, the heating time during the annealing treatment may be, for example, 1 to 30 hours, 2 to 25 hours, or 3 to 20 hours.

In the annealing step, the annealing treatment is performed once or more times. When the annealing treatment is performed multiple times, the annealing treatments will also be referred to as a first annealing treatment, a second annealing treatment, and the like in order, and steps of performing the respective annealing treatments will also be referred to as a first annealing step, a second annealing step, and the like in order. For example, in the above-described production method, when the annealing treatment is performed twice in the annealing step, it can be said that the annealing step includes: a step of obtaining a first annealed product by performing the first annealing treatment on the calcinated product; and a second annealing step of obtaining a second annealed product by performing the second annealing treatment on the first annealed product. In this case, the second annealed product corresponds to the above-described annealed product.

When the annealing treatment is performed two or more times in the annealing step, the temperature during the annealing treatment, the heating time, and the pressure during heating in the above-described annealing step are applicable to the temperature during the annealing treatment, the heating time, and the pressure during heating in the first annealing step, respectively. The temperature during the annealing treatment, the heating time, and the pressure during heating in and after the second annealing step may be the same as or different from those of the first annealing step. Note that, even when the temperature during the annealing treatment, the heating time, and the pressure during heating in and after the second annealing step are different from those of the first annealing step, these conditions are in the ranges of the conditions described regarding the above-described annealing step.

The number of times of the annealing treatment in the annealing step may be one, two or more, two to five, or two to four. By performing the annealing treatment multiple times, the β-sialon crystal defect density in the annealed product can be reduced, and a europium-containing β-sialon phosphor having a higher internal quantum efficiency can be obtained.

When the annealing treatment in the annealing step is performed multiple times, titanium oxide (Ti₂O₃) may be collectively blended in the first annealing step or may be dividedly blended in a plurality of annealing steps. Note that titanium oxide is collectively preferably blended in the first annealing step. Incidentally, when these compounds and the like are dividedly blended, the description regarding the blending amount of titanium oxide (Ti₂O₃) is applied except that the blend amount is replaced with the total amount of titanium oxide (Ti₂O₃) blended in a plurality of annealing steps. In the annealing step, the compound having elements as constituent elements of the β-sialon phosphor may be added together with titanium oxide (Ti₂O₃).

The method for producing the β-sialon phosphor may include other steps in addition to the calcination step and the annealing step. Examples of the other steps include a step of treating the annealed product obtained in the annealing step with at least one of an acid and an alkali and a classification step of adjusting the particle size of the annealed product or the annealed product having undergone the acid treatment or the like. The step of treating the annealed product with an acid will be referred to as an acid treatment step, and the step of treating the annealed product with an alkali will be referred to as an alkali treatment step.

Through the acid treatment step or the alkali treatment step, for example, a further decrease in crystal defect density in the phosphor of the annealed product, removal of silicon present on the solid solution surface produced by thermal decomposition of β-sialon or the like, or removal of AlN polytypoid that is a pseudo-polymorph of aluminum nitride (AlN) produced as a by-product during the preparation of a first calcinated product can be expected. The acid contains, for example, hydrofluoric acid or nitric acid. The acid can be a mixed acid of hydrofluoric acid and nitric acid. The alkali contains, for example, sodium hydroxide.

The classification step may be performed by, for example, any one of a wet classification method and a dry classification method. Examples of the dry classification include an elutriation classification method in which the annealed product is added to a mixed solvent containing ion exchange water and a disperser (for example, sodium hexametaphosphate) or a mixed solvent containing ion exchange water and ammonia water, is stirred, and is left to stand to remove particles having a small particle size.

### <Light-Emitting Device>

A light-emitting device according to the present embodiment includes a light-emitting light source and a wavelength conversion member. The wavelength conversion member contains a phosphor. This phosphor contains the β-sialon phosphor powder according to the first embodiment and/or the β-sialon phosphor powder according to the second embodiment.

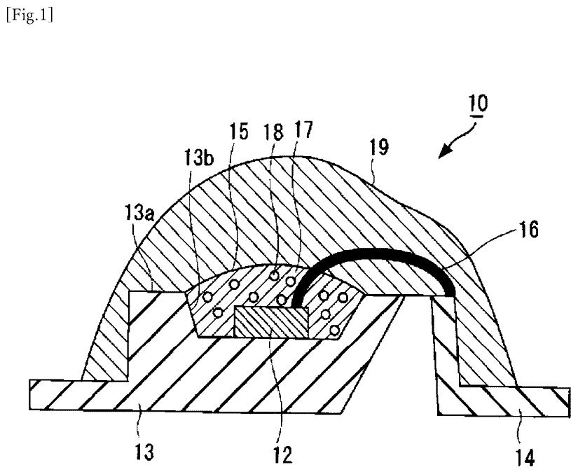

FIG. 1 is a cross-sectional view schematically showing an example of a structure of a light-emitting device 10.

The light-emitting device 10 shown in FIG. 1 includes an LED chip as a light-emitting light source 12, a first lead frame 13 on which the light-emitting light source 12 is mounted, a second lead frame 14, a wavelength conversion member 15 that covers the light-emitting light source 12, a bonding wire 16 that electrically connects the light-emitting light source 12 and the second lead frame 14, and a cap 19 formed of a synthetic resin that covers these members. The wavelength conversion member 15 has a phosphor 18 and a sealing resin 17 in which the phosphor 18 is dispersed.

On an upper portion 13a of the first lead frame 13, a recess portion 13b is formed for mounting a light emitting diode chip as the light-emitting light source 12. The recess portion 13b has a substantially funnel shape in which the hole diameter gradually expands upward from the bottom surface thereof, and the inner surface of the recess portion 13b serves as a reflecting surface. An electrode on the lower surface side of the light-emitting light source 12 is die-bonded to a bottom surface of the reflecting surface. Another electrode formed on an upper surface of the light-emitting light source 12 is connected to a surface of the second lead frame 14 through the bonding wire 16.

Various LED chips can be used as the light-emitting light source 12. The light-emitting light source 12 is still more preferably an LED chip that generates light having a wavelength of more than or equal to 300 nm and less than or equal to 500 nm as a wavelength of near-ultraviolet light to blue light.

This phosphor 18 used in the wavelength conversion member 15 of the light-emitting device 10 contains the β-sialon phosphor powder according to the first embodiment and/or the β-sialon phosphor powder according to the second embodiment. In addition, from the viewpoint of controlling the light wavelength control of the light-emitting device 10, the phosphor 18 may further contain a phosphor such as a simple substance or a mixture of an α-sialon phosphor, a KSF-based phosphor, CaAlSiN₃, or YAG, in addition to the β-sialon phosphor powder according to the first embodiment and/or the β-sialon phosphor powder according to the second embodiment. Examples of the element dissolved in these phosphors include europium (Eu), cerium (Ce), strontium (Sr), calcium (Ca), and manganese (Mn). These phosphors may be used alone or in combination of two or more.

Among these, the phosphor used in combination with the β-sialon phosphor powder according to the first embodiment and/or the β-sialon phosphor powder according to the second embodiment is preferably a KSF-based phosphor in which manganese is dissolved. A combination of the β-sialon phosphor emitting green light and the KSF-based phosphor emitting red light can be suitably used as a backlight LED suitable for a high color rendering TV or the like.

By combining the light-emitting light source 12 and the wavelength conversion member 15, light having a high emission intensity can be emitted.

Just to be sure, the KSF-based phosphor in which manganese is dissolved can be represented by Formula: A₂M₍₁₋ₙ₎F₆:Mn⁴⁺ₙ. In this formula, the element A represents one or more alkali metal elements containing K, the element M represents a Si simple substance, a Ge simple substance, or a combination of Si and one or more elements selected from the group consisting of Ge, Sn, Ti, Zr, and Hf, and 0<n≤0.1.

The light-emitting device 10 using the β-sialon phosphor has emission characteristics of emitting green light having a peak at a wavelength in a range of more than or equal to 520 nm and less than or equal to 560 nm by irradiation with particularly near-ultraviolet light or visible light having a wavelength of more than or equal to 300 nm and less than or equal to 500 nm as an excitation source from the light-emitting light source 12. Therefore, by using a near-ultraviolet LED chip or a blue LED chip as the light-emitting light source 12 and the β-sialon phosphor of the present embodiment in combination with a simple substance or a mixture of a red light-emitting phosphor, a blue light-emitting phosphor, a yellow light-emitting phosphor, or an orange light-emitting phosphor having a wavelength of more than or equal to 600 nm and less than or equal to 700 nm, white light can be realized.

Hereinabove, the embodiment of the present invention has been described. However, the embodiment is merely an example of the present invention, and various configurations other than the above-described configurations can be adopted. In addition, the present invention is not limited to the above-described embodiment, and modifications, improvements, and the like within a range where the object of the present invention can be achieved are included in the present invention.

### EXAMPLES

The embodiments of the present invention will be described in more detail based on Examples and Comparative Examples. Just to be sure, the present invention is not limited to only Examples.

### <Production of β-Sialon Phosphor Particles>

### Example 1

The following steps (1) to (4) were performed.

### (1) Raw Material Mixing Step

Raw materials were weighed into a container such that the proportion of silicon nitride (Si₃N₄) was 95.7 mass %, the proportion of aluminum nitride (AlN) was 2.6 mass %, the proportion of aluminum oxide (Al₂O₃) was 1.0 mass %, and the proportion of europium oxide (Eu₂O₃) was 0.7 mass %, and were mixed using a V-shape mixer (manufactured by Tsutsui Scientific Instruments Co., Ltd.) to obtain a mixture. The obtained mixture was allowed to pass through a sieve having an aperture of 250 μm to remove aggregates. As a result, a raw material composition was obtained. Aggregates that were not able to pass through the sieve were ground to adjust the particle size such that the ground aggregates passed through the sieve.

### (2) Calcination Step

200 g of the above-described raw material composition was put into a covered cylindrical boron nitride container (manufactured by Denka Company Limited, a molded product containing boron nitride (trade name: DENKA BORON NITRIDE N−1) as a major component, inner diameter: 10 cm, height: 10 cm). Next, this container was disposed in an electric furnace including a carbon heater, was heated to 2020° C. in a nitrogen gas atmosphere (pressure: 0.90 MPaG), and was heated at the heating temperature of 2020° C. for 8 hours (calcination step). After the heating, a sample that loosely aggregated in a lump in the container was crushed in a mortar. The crushed sample was allowed to pass through a sieve having an aperture of 250 μm and was strongly ground. This way, a powdered first calcinated product was obtained.

### (3) Annealing Step

The first calcinated product and titanium oxide (Ti₂O₃) were mixed with each other to obtain a mixture for an annealing treatment. The amount of titanium oxide was adjusted to 0.1 parts by mass with respect to 100 parts by mass of the total amount of the first calcinated product and titanium oxide.

The mixture for an annealing treatment was filled in the cylindrical boron nitride container. This container was disposed in an electric furnace including a carbon heater. The container was heated to 1450° C. in an argon gas atmosphere (pressure: 0.025 MPaG), and was heated at the temperature of 1450° C. for 3 hours (annealing step). After the heating, the lump material where the particles loosely aggregated in the container was crushed in a mortar, and was allowed to pass through a sieve having an aperture of 250 μm to obtain powder.

### (4) Steps of Acid Treatment, Removal of Fine Powder, and the Like

The obtained powder was added to a mixed acid of hydrofluoric acid (concentration: 50 mass %) and nitric acid (concentration: 70 mass %) (mixture containing hydrofluoric acid and nitric acid at a volume ratio of 1:1), and was treated with an acid for 30 minutes under stirring at a temperature of 75° C. After completion of the acid treatment and the stirring, the powder was precipitated, and the supernatant liquid and fine powder purified in the acid treatment were removed. Next, distilled water was further added, and the solution was stirred again. After the stirring, the powder was precipitated, and the supernatant liquid and the fine powder were removed. This operation was repeated at a pH of the aqueous solution of less than or equal to 8 until the supernatant liquid was transparent, and the obtained precipitate was filtered and dried.

As a result, β-sialon phosphor powder containing the Eu-activated β-sialon phosphor particles was obtained.

### Example 2

(2) β-sialon phosphor powder was obtained using the same method as that of Example 1, except that weak grinding was performed instead of strong grinding as the final grinding of the calcination step.

### Example 3

(3) β-sialon phosphor powder was obtained using the same method as that of Example 1, except that the amount of titanium oxide added in the annealing step was changed from 0.1 parts by mass to 0.2 parts by mass.

### Comparative Example 1

(3) β-sialon phosphor powder was obtained using the same method as that of Example 1, except that an annealing treatment of heating only the first calcinated product was performed without using titanium oxide in the annealing step.

### Comparative Example 2

(3) β-sialon phosphor powder was obtained using the same method as that of Example 1, except that the same mass of europium oxide was added instead of titanium oxide for the annealing treatment in the annealing step.

### Comparative Example 3

(3) β-sialon phosphor powder was obtained using the same method as that of Example 2, except that an annealing treatment of heating only the first calcinated product was performed without using titanium oxide in the annealing step.

### <Line Analysis>

The analysis was performed according to the following procedure.

(1) A sample where the β-sialon phosphor powder was embedded with an epoxy resin was prepared.

(2) The sample prepared (1) above was set in a cross-section polisher (SM-09010, manufactured by JEOL Ltd.) and was treated under a condition of an accelerated voltage of 6 kV. As a result, a cross-section of the embedded β-sialon phosphor particles was exposed.

(3) The cross-section exposed in (2) above was observed with a SEM (field emission type, accelerated voltage: 5 kV) to specify a portion where a grain boundary (substantially linear grain boundary having a length of at least 200 nm from the particle surface) suitable for analysis was present. This portion and the periphery thereof were thinned by a focused ion beam (FIB) processing device to prepare a thin sample.

(4) In the thin sample (cross-section including the grain boundary), line analysis was linearly performed on elemental compositions of the grain boundary and both sides of the grain boundary in a direction perpendicular to the grain boundary at a depth of 200 nm from a portion of surfaces of the particles where the grain boundary was present. In the line analysis, JEM-ARM 200F manufactured by JEOL Ltd. (an apparatus where a scanning transmission electron microscope (STEM)) and an instrument capable of energy dispersive X-ray spectroscopy (EDS) were combined) was used. The accelerated voltage was set to 200 kV.

(5) The content (unit: atom %) of each of elements at each of the points such as the point P was obtained based on the result of the line analysis. The content (unit: atom %) of each of the elements was obtained by analysis using “NORAN System 7” manufactured by Thermo Fishier Scientific Inc. as accompanying software of JEM-ARM200F. In this analysis, Si, N, Al, O, Ti (K-line), and Eu (L-line) were designated as elements to be considered. In addition, a Cliff-Lorimer (no absorption) model was designated as a semi-quantitative model.

A “ratio” between the element contents, for example, N_{Eu}/N′_{Eu} was calculated from the obtained content of each of the elements.

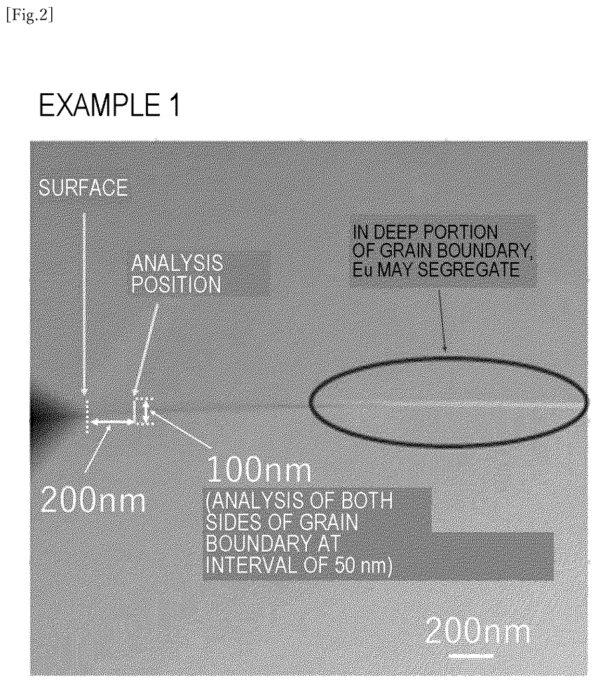

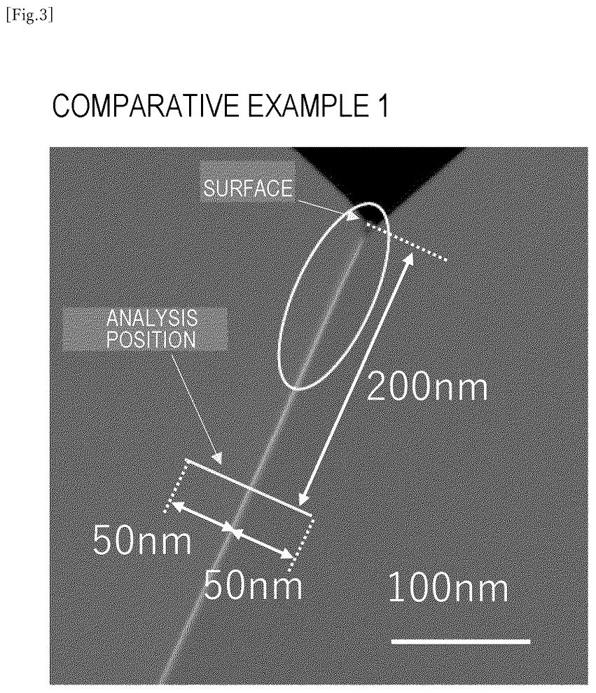

For reference, FIG. 2 shows positions where (4) the line analysis was performed on the thin sample obtained by thinning the β-sialon phosphor particles according to Example 1 as shown in (1) to (3) above. Likewise, FIG. 3 shows positions where (4) the line analysis was performed on the thin sample obtained by thinning the β-sialon phosphor particles according to Comparative Example 1 as shown in (1) to (3) above.

Table 1 shows the ratios between the content (unit: atom %) of each of the elements at each of the points and the ratios between the element contents such as N_{Eu}/N′_{Eu}.

It is considered that, even when the measurement point is shifted by about several nanometers in a region at a sufficient distance (about 50 nm) from the grain boundary, there is no significant difference in elemental composition. In consideration of this result, in Examples, the content of each of the elements measured at the position of the point Q_{(O)} was considered as the amount of each of the elements at the point Q.

TABLE 1

| | | Example | Example | Example | Comparative | Comparative | Comparative |
|---|---|---|---|---|---|---|---|
| | | 1 | 2 | 3 | Example 1 | Example 2 | Example 3 |
| Content of Each | N_{N} | 18.58 | 12.4 | 27.7 | 32.50 | 17.03 | 27.57 |
| Element at Point | N_{O} | 0.64 | 13.2 | 7.5 | 2.38 | 1.26 | 3.47 |
| P (atom %) | | | | | | | |
| Content of Al at | N_{Al} | 2.78 | 1.5 | 2.4 | 4.61 | 16.75 | 3.58 |
| Point P_{(Al)} | | | | | | | |
| (atom %) | | | | | | | |
| Content of Each | N_{Si} | 77.79 | 73.0 | 63.2 | 58.43 | 62.85 | 62.69 |
| Element at Point | N_{Ti} | 0.05 | 0.1 | 0.0 | 0.06 | 0.15 | 0.00 |
| P (atom %) | N_{Eu} | 0.22 | 0.11 | 0.195 | 2.02 | 2.17 | 2.68 |
| Content of Each | N_{N(O)} | 18.56 | 8.05 | 19.54 | 31.53 | 16.28 | 27.6 |
| Element at Point | N_{O(O)} | 2.92 | 38.50 | 21.35 | 2.56 | 1.62 | 3.5 |
| P_{(O)} (atom %) | N_{Al(O)} | 2.36 | 0.30 | 1.79 | 4.48 | 16.75 | 3.6 |
| | N_{Si(O)} | 76.00 | 53.02 | 57.30 | 59.44 | 63.19 | 62.7 |
| | N_{Ti(O)} | 0.00 | 0.12 | 0.03 | 0.06 | 0.27 | 0.0 |
| | N_{Eu(O)} | 0.16 | 0.02 | 0.00 | 1.92 | 1.89 | 2.7 |
| Content of Each | N′_{N} | 19.17 | 15.68 | 19.87 | 32.95 | 16.82 | 29.1 |
| Element at Point | N′_{O} | 0.58 | 6.91 | 0.14 | 1.39 | 0.82 | 0.60 |
| Q_{(Q)} (atom %) | N′_{Al} | 2.76 | 1.76 | 1.87 | 2.12 | 14.95 | 1.25 |
| (Also Considered | N′_{Si} | 77.36 | 75.49 | 78.01 | 63.31 | 66.48 | 69.0 |
| as Content of | N′_{Ti} | 0.00 | 0.07 | 0.04 | 0.01 | 0.23 | 0.084 |
| Each Element at | N′_{Eu} | 0.13 | 0.09 | 0.07 | 0.23 | 0.69 | 0.02 |
| Point Q) | | | | | | | |
| Elemental | (N_{Eu}/N_{O})/ | 1.51 | 0.66 | 0.05 | 5.19 | 2.04 | 18.58 |
| Composition | (N′_{Eu}/N′_{O}) | | | | | | |
| Ratio (First | (N_{Al}/N_{O})/ | 0.91 | 0.46 | 0.02 | 1.27 | 0.73 | 0.49 |
| Embodiment) | (N′_{Al}/N′_{O}) | | | | | | |
| | N_{Eu}/N_{O} | 0.35 | 0.01 | 0.03 | 0.85 | 1.72 | 0.77 |
| | N_{Al}/N_{O} | 4.33 | 0.12 | 0.32 | 1.94 | 13.27 | 1.03 |
| | N_{Eu}/N′_{Eu} | 1.67 | 1.25 | 2.74 | 8.89 | 3.14 | 108.04 |
| | N_{Al}/N′_{Al} | 1.01 | 0.87 | 1.27 | 2.18 | 1.12 | 2.86 |
| Elemental | (N_{Eu(O)}/N_{O(O)})/ | 0.24 | 0.03 | 0.00 | 4.58 | 1.38 | 18.58 |
| Composition | (N′_{Eu(O)}/N′_{O(O)}) | | | | | | |
| Ratio (Second | (N_{Al(O)}/N_{O(O)})/ | 0.17 | 0.03 | 0.01 | 1.15 | 0.57 | 0.49 |
| Embodiment) | (N′_{Al(O)}/N′_{O(O)}) | | | | | | |
| | N_{Eu(O)}/N_{O(O)} | 0.06 | 0.00 | 0.00 | 0.75 | 1.16 | 0.77 |
| | N_{Al(O)}/N_{O(O)} | 0.81 | 0.01 | 0.08 | 1.75 | 10.31 | 1.03 |
| | N_{Eu(O)}/N′_{Eu(O)} | 1.23 | 0.19 | 0.00 | 8.44 | 2.74 | 108.04 |
| | N_{Al(O)}/N′_{Al(O)} | 0.85 | 0.17 | 0.96 | 2.12 | 1.12 | 2.86 |

### <Evaluation of Internal Quantum Efficiency or the Like>

Regarding the β-sialon phosphor obtained in each of Examples and Comparative Examples, an absorptance, an internal quantum efficiency, an external quantum efficiency, and a chromaticity X during irradiation with excitation light having a wavelength of 455 nm were evaluated. In addition, an absorptance during irradiation with excitation light having a wavelength of 600 nm was evaluated. A specific evaluation method is as follows.

### [Absorptance, Internal Quantum Efficiency, and External Quantum Efficiency]

The absorptance (excitation light absorptance), the internal quantum efficiency, and the external quantum efficiency of the phosphor during irradiation with excitation light having a wavelength of 455 nm were calculated in the following procedure. First, the phosphor to be measured was filled in a recessed cell such that the surface was smooth, and was attached to an opening portion of an integrating sphere. Monochromatic light having a wavelength of 455 nm dispersed from a Xe lamp as a light-emitting light source was introduced as excitation light of the phosphor into the integrating sphere using an optical fiber. The phosphor to be measured was irradiated with the monochromatic light as the excitation light to measure a fluorescence spectrum. For the measurement, a spectrophotometer (trade name: MCPD-7000, manufactured by Otsuka Electronics Co., Ltd.) was used.

The emission intensity of the phosphor was determined based on the data of the obtained fluorescence spectrum. In addition, the number of excitation reflected light photons (Qref) and the number of fluorescence photons (Qem) were calculated from the data of the obtained fluorescence spectrum. The number of excitation reflected light photons was calculated in the same wavelength range as that of the number of excitation light photons, and the number of fluorescence photons was calculated in a wavelength range of 465 to 800 nm. In addition, using the same device, a standard reflective plate (SPECTRALON (registered trademark), manufactured by Labsphere) having a reflectivity of 99% was attached to the opening portion of the integrating sphere to measure the spectrum of the excitation light having a wavelength of 455 nm. At this time, the number of excitation light photons (Qex) was calculated from the spectrum in a wavelength range of 450 to 465 nm.

The absorptance, the internal quantum efficiency, and the external quantum efficiency of the phosphor to be measured with respect to the excitation light at 455 nm were obtained from a calculation expression below based on the above-described calculation results.

$$Absorptance of Excitation Light at 455 nm = ( ( Qex - Qref ) / Qex ) \times 100$$

$$Internal Quantum Efficiency = ( Qem / ( Qex - Qref ) ) \times 100$$

$$External Quantum Efficiency = ( Qem / Qex ) \times 100$$

A relational expression of the external quantum efficiency, the absorptance of the excitation light at 455 nm, and the internal quantum efficiency can be represented as follows based on the above-described expression.

External Quantum Efficiency=Absorptance of Light at 455 nm×Internal Quantum Efficiency

### [Chromaticity X and Chromaticity Y]

From the spectral data in a wavelength range of 465 to 780 nm of the fluorescence spectrum, the chromaticity X and the chromaticity Y were obtained by calculating an x value (chromaticity X) and a y value (chromaticity Y) of CIE chromaticity coordinates in the XYZ colorimetric system defined by JIS Z8781-3:2016 according to JIS Z8724:2015.

[Absorptance of Light at 600 nm]

A standard reflective plate (SPECTRALON (registered trademark), manufactured by Labsphere) having a reflectivity of 99% was set in a side opening portion of the integrating sphere. Monochromatic light having a wavelength of 600 nm dispersed from a light-emitting light source (Xe lamp) was introduced into the integrating sphere using an optical fiber, and a reflected light spectrum was measured by a spectrophotometer (MCPD-7000, manufactured by Otsuka Electronics Co., Ltd.). At this time, the number of incident light photons (Qex (600)) was calculated from the spectrum in a wavelength range of 590 to 610 nm.

Next, the β-sialon phosphor was filled in a recessed cell such that the surface was smooth, was set in an opening portion of the integrating sphere, and was irradiated with monochromatic light having a wavelength of 600 nm to measure an incident reflected light spectrum using a spectrophotometer. The number of incident reflected light photons (Qref (600)) was calculated from the obtained spectral data. The number of incident reflected light photons (Qref (600)) was calculated in the same wavelength range as the number of incident light photons (Qex (600)). From the obtained two number of photons, the absorptance of the light at 600 nm was calculated from the following expression.

Absorptance of Light at 600 nm=((Qex(600)−Qref(600))/Qex(600))×100

### <Measurement of D50>

D50 of the β-sialon phosphor according to each of Examples and Comparative Examples was measured. A specific procedure or conditions of the measurement were as described above.

The evaluation and the measurement results are collectively shown in Table 2.

TABLE 2

| | | Example | Example | Example | Comparative | Comparative | Comparative |
|---|---|---|---|---|---|---|---|
| | | 1 | 2 | 3 | Example 1 | Example 2 | Example 3 |
| Evaluation of | Absorptance | 82% | 84% | 83% | 81% | 82% | 84% |
| Light having | Internal Quantum | 82% | 83% | 84% | 79% | 79% | 79% |
| Wavelength | Efficiency | | | | | | |
| of 455 nm | External Quantum | 67% | 70% | 70% | 64% | 65% | 66% |
| | Efficiency | | | | | | |
| | Chromaticity x | 0.379 | 0.378 | 0.372 | 0.377 | 0.374 | 0.375 |
| | Chromaticity y | 0.605 | 0.607 | 0.611 | 0.607 | 0.610 | 0.610 |
| Evaluation of | Absorptance | 6% | 4% | 6% | 8% | 7% | 5% |
| Light having | | | | | | | |
| Wavelength | | | | | | | |
| of 600 nm | | | | | | | |
| Particle Size | D50 (Unit: μm) | 16.2 | 23.0 | 22.8 | 17.0 | 16.1 | 24.2 |
| Distribution | | | | | | | |

As shown in Tables 1 and 2, the internal quantum efficiencies according to Examples 1 to 3 where the value of N_{Eu}/N′_{Eu} was less than or equal to 3.00 and/or the value of N_{Eu(O)}/N′_{Eu(O)} was less than or equal to 2.50 were higher than the internal quantum efficiencies according to Comparative Examples 1 to 3 where the value of N_{Eu}/N′_{Eu} was more than 3.00 and/or the value of N_{Eu(O)}/N′_{Eu(O)} was more than 2.50.

In addition, it is understood from “a difference in preparation method” between Examples and Comparative Examples that the annealing treatment using titanium oxide is a preferable method for obtaining the β-sialon phosphor particles where the value of N_{Eu}/N′_{Eu} is less than or equal to 3.00 and/or the value of N_{Eu(O)}/N′_{Eu(O)} is less than or equal to 2.50.

The present application claims priority based on Japanese Patent Application N_{O}. 2022-034169 filed on Mar. 7, 2022, the entire content of which is incorporated herein by reference.

### REFERENCE SIGNS LIST

10 light-emitting device
12 light-emitting light source (LED chip)
13 first lead frame
13a upper portion
13b recess portion
14 second lead frame
15 wavelength conversion member
16 bonding wire
17 sealing resin
18 phosphor (β-sialon phosphor particle)
19 cap

1. Eu-activated β-sialon phosphor particles having a grain boundary,
wherein in a cross-section including the grain boundary, when line analysis is linearly performed on elemental compositions of the grain boundary and both sides of the grain boundary in a direction perpendicular to the grain boundary at a depth of 200 nm from a portion of surfaces of the particles where the grain boundary is present,
on a line segment on which the line analysis is performed, a value of NEu/N′Eu is less than or equal to 3.00, where (i) NEu represents an Eu content at a point P of the grain boundary having a peak of the Eu content and (ii) N′Eu represents an Eu content at a point Q at a distance of 50 nm from the point P.

2. The β-sialon phosphor particles according to claim 1,
wherein a value of (NEu/NO)/(NEu′/NO′) is less than or equal to 2.00, where NO represents an oxygen content at the point P and N′O represents an oxygen content at the point Q.

3. The β-sialon phosphor particles according to claim 1,
wherein a value of NEu/NO is less than or equal to 0.70, where NO represents an oxygen content at the point P.

4. The β-sialon phosphor particles according to claim 1,
wherein when the line analysis is linearly performed on the elemental compositions of the grain boundary and both sides of the grain boundary in the direction perpendicular to the grain boundary at a depth of 200 nm from the portion of the surfaces of the particles where the grain boundary is present,
on the line segment on which the line analysis is performed, a value of NAl/NO is less than or equal to 1.00, where NO represents an oxygen content at the point P and NAl represents an Al content at a point P(Al) of the grain boundary having a peak of the Al content.

5. Eu-activated β-sialon phosphor particles having a grain boundary,
wherein in a cross-section including the grain boundary, when line analysis is linearly performed on elemental compositions of the grain boundary and both sides of the grain boundary in a direction perpendicular to the grain boundary at a depth of 200 nm from a portion of surfaces of the particles where the grain boundary is present,
on a line segment on which the line analysis is performed, a value of NEu(O)/N′Eu(O) is less than or equal to 2.50, where (i) NEu(O) represents an Eu content at a point P(O) of the grain boundary having a peak of an O content and (ii) N′Eu(O) represents an Eu content at a point Q(O) at a distance of 50 nm from the point P(O).

6. The β-sialon phosphor particles according to claim 5,
wherein a value of (NEu(O))/NO(O))/(N′Eu(O)/N′O(O)) is less than or equal to 1.20, where NO(O) represents an oxygen content at the point P(O) and N′O(O) represents an oxygen content at the point Q(O).

7. The β-sialon phosphor particles according to claim 5,
wherein a value of NEu(O)/NO (O) is less than or equal to 0.70, where NO(O) represents an oxygen content at the point P(O).

8. The β-sialon phosphor particles according to claim 5,
wherein a value of NAl(O)/NO(O) is less than or equal to 1.00, where NO(O) represents an oxygen content at the point P(O) and NAl(O) represents an aluminum content at the point P(O).

9. β-sialon phosphor powder comprising the β-sialon phosphor particles according to claim 1 or 5.

10. A light-emitting device comprising:
a light-emitting light source; and
a wavelength conversion member,
wherein the wavelength conversion member contains phosphor powder, and
the phosphor powder contains the β-sialon phosphor powder according to claim 9.

11. The light-emitting device according to claim 10,
wherein the light-emitting light source includes an LED chip that generates light having a wavelength of more than or equal to 300 nm and less than or equal to 500 nm.
